(19) United States
(12) Patent Application Publication
(10) Pub. No.: US 2023/0163127 A1
(43) Pub. Date: May 25, 2023

(54) STACKED NANOSHEET DEVICES WITH MATCHED THRESHOLD VOLTAGES FOR NFET/PFET

(71) Applicant: INTERNATIONAL BUSINESS MACHINES CORPORATION, ARMONK, NY (US)

(72) Inventors: Heng Wu, Guilderland, NY (US); Julien Frougier, Albany, NY (US); Chen Zhang, Guilderland, NY (US); ZUOGUANG LIU, Schenectady, NY (US); Ruilong Xie, Niskayuna, NY (US); Alexander Reznicek, Troy, NY (US)

(21) Appl. No.: 17/455,941

(22) Filed: Nov. 22, 2021

(51) Int. Cl. H01L 27/092; H01L 29/06; H01L 29/423; H01L 29/49; H01L 29/786; H01L 21/02; H01L 21/28; H01L 21/8238; H01L 29/66

(52) U.S. Cl. CPC H01L 27/0922; H01L 29/0665; H01L 29/42392; H01L 29/4908; H01L 29/78696; H01L 21/0259; H01L 21/28088; H01L 21/823807; H01L 21/823842; H01L 29/66742

(57) ABSTRACT

A semiconductor device includes a lower nano device that includes a plurality of stacked first nano sheets, where the first nano sheets are spaced apart from each other a first distance. An upper nano device that includes a plurality of stacked second nano sheets, where the second nano sheets are spaced apart from each other a second distance, where the second distance is larger than the first distance.

### BACKGROUND

The present invention generally relates to the field of nano devices, and more particularly stacked nanodevices having different geometries.

Nanosheet is one of the most promising technology in 5 nm and beyond development. Area scaling is critical to reduce the cost and increase the integration density. By stacking the nanosheet nFETs and pFETs together in 3D space, the area can be greatly reduced by half. The current stacked nanosheet devices uses common WFM for both NFET and PFET, which is not suitable for Vt matching purpose in real CMOS circuits. To realize different WFM on top and bottom transistors requires additional patterning/etch/deposition process, which is complicated and may introduce extra process variations.

### BRIEF SUMMARY

Additional aspects and/or advantages will be set forth in part in the description which follows and, in part, will be apparent from the description, or may be learned by practice of the invention.

A semiconductor device includes a lower nano device that includes a plurality of stacked first nano sheets, where the first nano sheets are spaced apart from each other a first distance. An upper nano device that includes a plurality of stacked second nano sheets, where the second nano sheets are spaced apart from each other a second distance, where the second distance is larger than the first distance.

A semiconductor device including a lower nano device that includes a plurality of stacked first nano sheets and a PFET material located around the plurality of stacked first nano sheets, where the first nano sheets are spaced apart from each other a first distance. An upper nano device that includes a plurality of stacked second nano sheets a NFET material located around the plurality of stacked second nano sheets, where the second nano sheets are spaced apart from each other a second distance, where the second distance is larger than the first distance.

A method manufacturing a semiconductor device including forming a lower nano device that includes a plurality of stacked first nano sheets and a plurality of first sacrificial layers, where a first sacrificial layer is located above and/or below each of the first nano sheets, where the each of the plurality of first sacrificial layers has a first thickness T1. Forming an upper nano device that includes a plurality of stacked second nano sheets and a plurality of second sacrificial layers, where a second sacrificial layer is located above and/or below each of the second nano sheets, where the each of the plurality of second sacrificial layers has a second thickness T2, where the second thickness T2 is greater than the first thickness T1.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a nano stack, in accordance with an embodiment of the present invention.

FIG. 2 illustrates the nano stack after an initial patterning stage, in accordance with the embodiment of the present invention.

FIG. 3 illustrates the nano device after replacing the first group of sacrificial layers, in accordance with the embodiment of the present invention.

FIG. 4 illustrates the nano device after etching of the nano stack, in accordance with the embodiment of the present invention.

FIG. 5 illustrates the nano device after recessing back the sacrificial layers and the formation of an inner spacer, in accordance with the embodiment of the present invention.

FIG. 6 illustrates the nano device after the formation of the first source/drain epi, in accordance with the embodiment of the present invention.

FIG. 7 illustrates the nano device after the recessing the first source/drain epi, in accordance with the embodiment of the present invention.

FIG. 8 illustrates the nano device after the formation of a dielectric layer and the second source/drain epi, in accordance with the embodiment of the present invention.

FIG. 9 illustrates the nano device after the formation of an interlayered dielectric layer, in accordance with the embodiment of the present invention.

FIG. 10 illustrates the nano device after the removal the sacrificial layers, in accordance with the embodiment of the present invention.

FIG. 11 illustrates the nano device after the formation of oxide layer and a High K layer, in accordance with the embodiment of the present invention.

FIG. 12 illustrates the nano device after the formation a first metal layer, in accordance with the embodiment of the present invention.

FIG. 13 illustrates the nano device after the formation a second metal layer, in accordance with the embodiment of the present invention.

FIG. 14 illustrates the nano device after the formation a metal cap, in accordance with the embodiment of the present invention.

FIG. 15 illustrates the nano device after the formation a metal connector, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. This present invention illustrates a new way to enable different critical voltages (W_{FM}) for NFET and PFET in stacked nanosheet devices, delivering better and balanced Vt. An initial nano stack is formed comprised of alternating layers of sacrificial materials and channel material to form the NFET and PFET device. Usually, each sacrificial layer has the same thickness, thus allowing the uniform processing of the nano stack. In contrast, the present invention is utilizing different thicknesses for the sacrificial layers in the nano stack. The sacrificial layers that will be part of the lower device has a thickness T₁ and the sacrificial layers that will be part of the upper device has a thickness T₂. Where thickness T₂ is greater than thickness T₁. The differences in the thickness of the sacrificial layers allow for the processing of the sacrificial layers to be different. Alternatively, thickness T₂ can be smaller than thickness T₁.

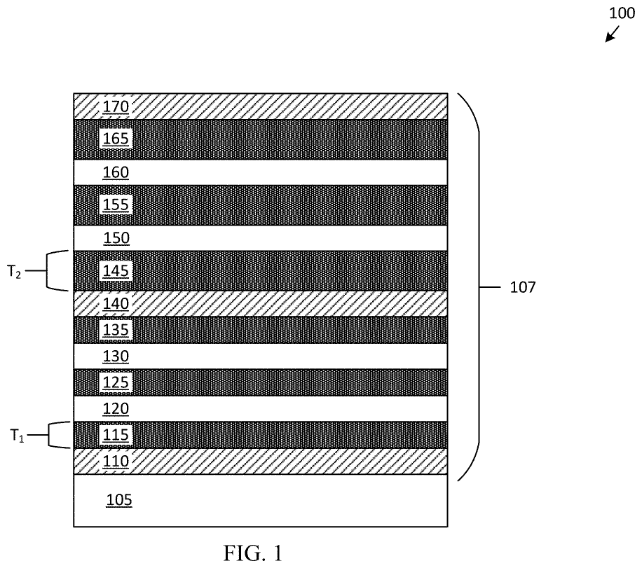

FIG. 1 illustrates a nano stack, in accordance with an embodiment of the present invention. The nano device 100 includes a substrate 105 and a nano stack 107 located on top of the substrate 105. The substrate 105, can be, for example, a material including, but not necessarily limited to, silicon (Si), silicon germanium (SiGe), silicon carbide (SiC), Si:C (carbon doped silicon), silicon germanium carbide (SiGeC), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or entire semiconductor substrate 105 may also be comprise of an amorphous, polycrystalline, or monocrystalline. The nano stack 107 is comprised of multiple layers. The nano stack 107 includes a first layer 110, a second layer 115, a third layer 120, a fourth layer 125, a fifth layer 130, a sixth layer 135, a seventh layer 140, an eighth layer 145, a ninth layer 150, a tenth layer 155, an eleven layer 160, a twelfth layer 1165, and a thirteenth layer 170. The number of layers illustrated are for example purposes only. A first group of sacrificial layers includes the first layer 110, the seventh layer 140 and the thirteenth layer 170. Each of the layers in the first group of sacrificial layers can be comprised of, for example, SiGe, where Ge is in the range of about 45% to 70%. A second group of sacrificial layers includes the second layer 115, the fourth layer 125, and the sixth layer 135. Each layer of the second group of sacrificial layers can be comprised of, for example, SiGe, where Ge is in the range of about 15% to 35%. Each layer in the second group of sacrificial layers has a thickness T₁. A third group of sacrificial layers includes the eighth layer 145, the tenth layer 155, and the twelfth layer 165. Each layer of the second group of sacrificial layers can be comprised of, for example, SiGe, where Ge is in the range of about 15% to 35%. Each layer in the second group of sacrificial layers has a thickness T₂. Where the thickness T₂ is greater than the thickness T₁. For example, thickness T₁ can be in the range of about 8 to 10 nm and the thickness T₂ can be in the range of about 12 to 13 nm. Alternatively, thickness T₁ can be greater than thickness T₂. The third layer 120, the fifth layer 130, ninth layer 150 and the eleventh layer 160 can be comprised of, for example, Si.

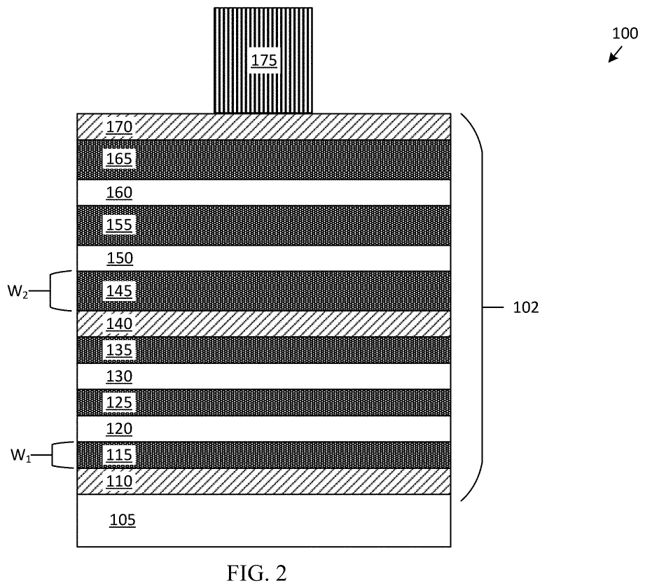

FIG. 2 illustrates the nano stack after an initial patterning stage, in accordance with the embodiment of the present invention. A hard mask 175 is formed on top of the thirteenth layer 170 and the hard mask 175 is etched to form the desired pattern.

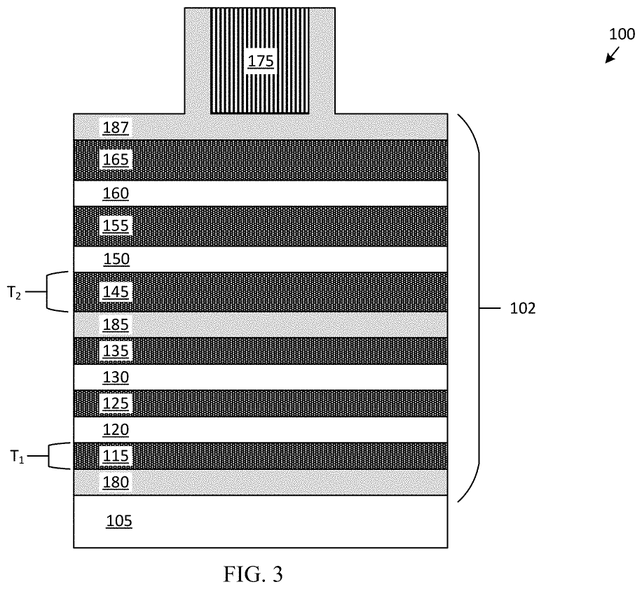

FIG. 3 illustrates the nano device 100 after replacing the first group of sacrificial layers, in accordance with the embodiment of the present invention. The first group of sacrificial layers, i.e., the first layer 110, the seventh layer 140 and the thirteenth layer 170, are selectively removed and replaced. These layers can be selectively targeted and removed because of the higher concentration of Ge when compared to the other layers. The first layer 110 is removed and replaced with a bottom dielectric layer 180. The seventh layer 140 and the thirteenth layer 170 are removed and replaced with a middle spacer 185 and a top spacer 187, respectively. The top spacer 187 extends up the sidewalls of the hard mask 175, as illustrated by FIG. 3. Therefore, the top spacer 187 is located on three sides of the hard mask 175.

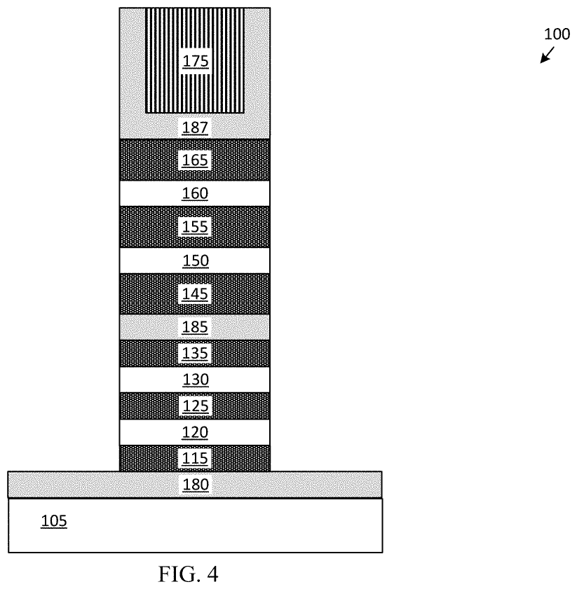

FIG. 4 illustrates the nano device 100 after etching of the nano stack, in accordance with the embodiment of the present invention. The nano stack 107 is etched to form a column as illustrated by FIG. 4. The nano stack 107 is etched down to the bottom dielectric layer 180, where the bottom dielectric layer 180 is used as an etch stop for the etching process. The etching process can be, for example, reactive ion etching (RIE). The nano stack 107 is etched to a width to include the top spacer 187 that extends up the sidewalls of the hard mask 175. The top spacer 187 has a U-shape such that the hard mask 175 is located within the U-shape of the top spacer.

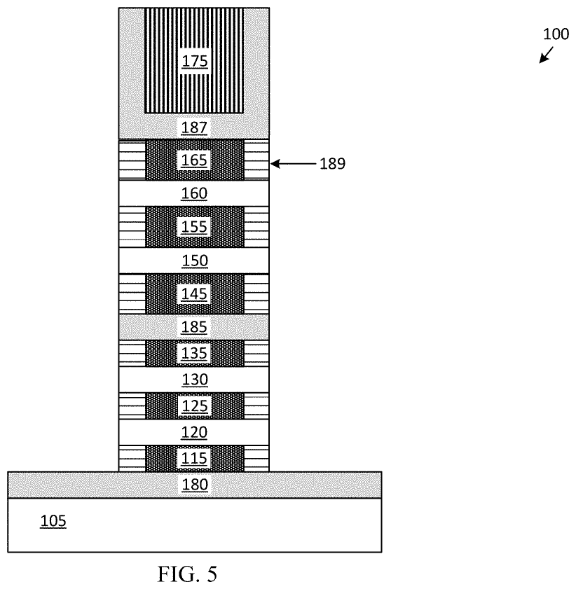

FIG. 5 illustrates the nano device after recessing back the sacrificial layers and the formation of an inner spacer, in accordance with the embodiment of the present invention. Each layer of the second group of sacrificial layers (i.e., the second layer 115, the fourth layer 125, and the sixth layer 135) and the third group of sacrificial layers (i.e., the eighth layer 145, the tenth layer 155, and the twelfth layer 165) are recessed back to create space for the formation of the inner spacer 189. The inner spacer 189 is formed in the spaced created by the recessing of the second and third groups of sacrificial layers.

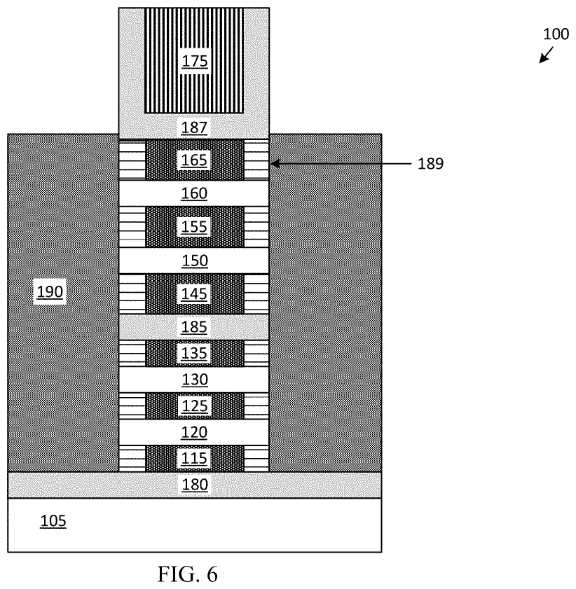

FIG. 6 illustrates the nano device 100 after the formation of the first source/drain epi 190, in accordance with the embodiment of the present invention. A first source/drain epi 190 is formed on top of the bottom dielectric layer 180 and around the nano stack 107. The first source/drain epi 190 can be a PFET material, for example, heavily doped SiGe.

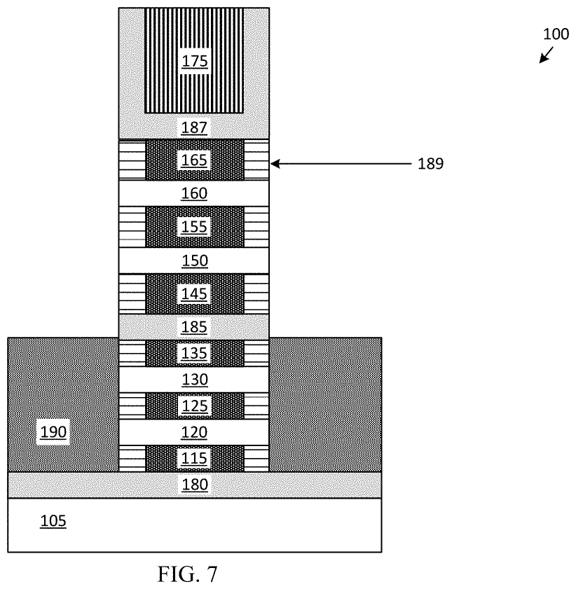

FIG. 7 illustrates the nano device 100 after the recessing the first source/drain epi 190, in accordance with the embodiment of the present invention. The first source/drain epi 190 is recessed so that the layer extends from the bottom dielectric layer 180 to within the thickness of the middle spacer 185.

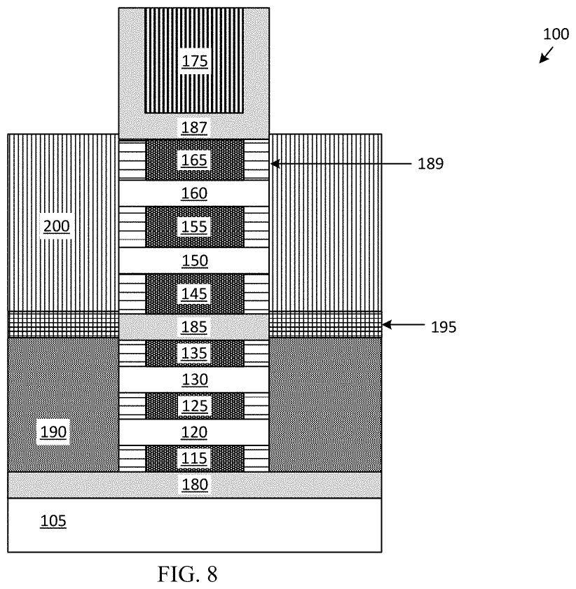

FIG. 8 illustrates the nano device 100 after the formation of a dielectric layer 195 and the second source/drain epi 200, in accordance with the embodiment of the present invention. A dielectric layer 195 is formed on top of the first source/drain epi 190. A dielectric layer 195 is formed on top of the first source/drain epi 190. A second source/drain epi 200 is formed on top of the dielectric layer 195 around the top portion of the nano stack 102. The second source/drain epi 200 can be a NFET material, for example, Si:P.

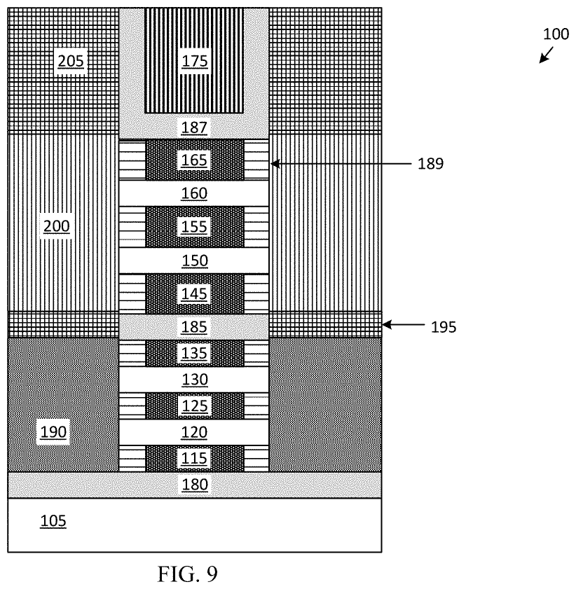

FIG. 9 illustrates the nano device 100 after the formation of an interlayered dielectric, in accordance with the embodiment of the present invention. An interlayered dielectric (ILD) 205 is formed on top of the second source/drain 200. The ILD 205 is located adjacent to the top spacer 187.

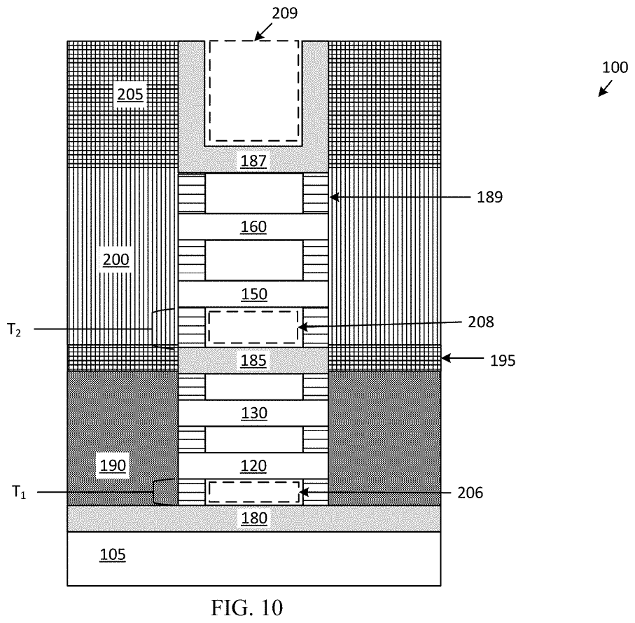

FIG. 10 illustrates the nano device 100 after the removal the sacrificial layers, in accordance with the embodiment of the present invention. The second group of sacrificial layers (i.e., the second layer 115, the fourth layer 125, and the sixth layer 135) are removed to create gaps 206 (as illustrated by dashed box) where the gap has a thickness T₁. The third group of sacrificial layers (i.e., the eighth layer 145, the tenth layer 155, and the twelfth layer 165) are removed to create gaps 208 (as illustrated by the dashed box) where the gap has a thickness T₂. Where the thickness T₂ (as illustrated by gap 208) in the upper section is greater than the thickness T₁ (as illustrated by dashed box for the gap 206) in the lower section. The hard mask 175 is also removed to create a gap 209 (as illustrated by the dashed box) between the vertical sections of the top spacer 187.

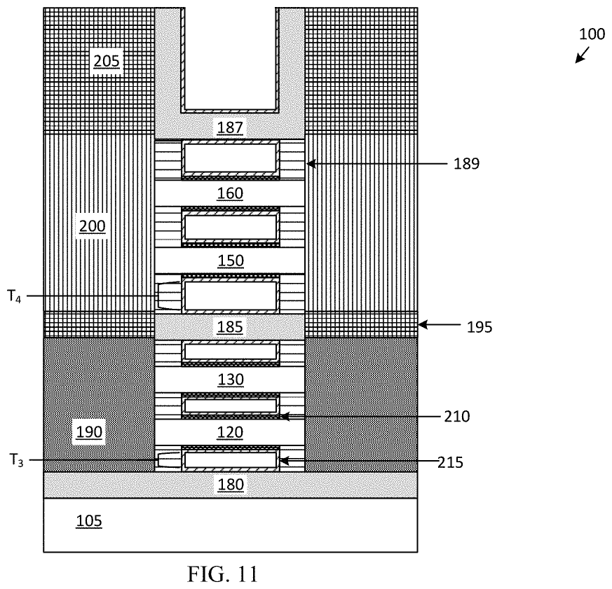

FIG. 11 illustrates the nano device 100 after the formation of oxide layer 210 and a High K layer 215, in accordance with the embodiment of the present invention. An oxide layer 210 is formed on the exposed surfaces of the third layer 120, the fifth layer 130, ninth layer 150 and the eleventh layer 160. A HK layer 215 is formed by example, atomic layer deposition (ALD), on the exposed surfaces within the gaps 206, 208, 209. The HK layer is formed on surfaces of the bottom dielectric layer 180, sidewalls of the inner spacer 189, the oxide layer 210, and the top spacer 187. After the deposition of the HK layer 215 remaining space within gap 206 has a thickness T₃ and the remaining space within gap 208 has a thickness T₄. Where thickness T₄ is greater than thickness T₃.

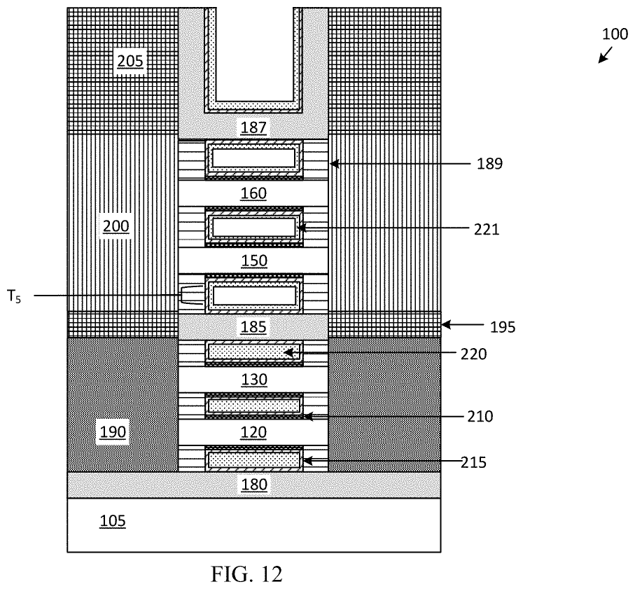

FIG. 12 illustrates the nano device 100 after the formation a first metal layer 220, in accordance with the embodiment of the present invention. A first metal layer 220 is formed by, for example, ALD to pinch off the gaps 206 in the lower section. The first metal layer 220 can be comprised of, for example, TiN. Since the thickness T₄ of gap 208 is greater than thickness T₃, then the gap 208 is not pinched off by the deposition of the first metal layer 220. The first metal layer 220 ends up forming a metal liner 221 on the inside exposed surfaces of the gap 208 and 209, thus the metal liner 221 is formed inside the U-shape of the top spacer 187. The remaining space in gap 208 has a thickness T₅.

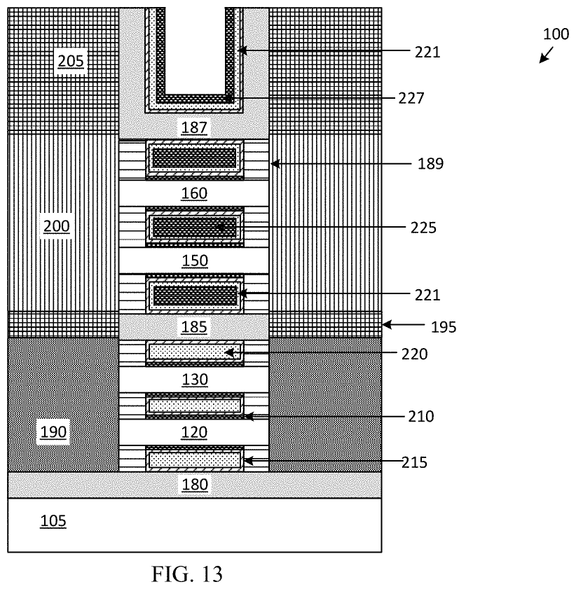

FIG. 13 illustrates the nano device 100 after the formation a second metal layer 225, in accordance with the embodiment of the present invention. A second metal layer 225 is formed by, for example, ALD, to pinch off gap 208. The second metal layer 228 can be comprised of, for example, TiC or TiAlC. Since the initial formation of the second group of sacrificial layers and the third group of sacrificial layers had different thickness (T₂>T₁) allows for the formation of different metal layers (e.g., the first metal layer 220 and the second metal layer 225) within the gaps (206 and 208) created by the removal of the sacrificial layers. The second metal layer 225 forms a second metal liner 227 on the exposed surface of the metal liner 221 in the gap 209.

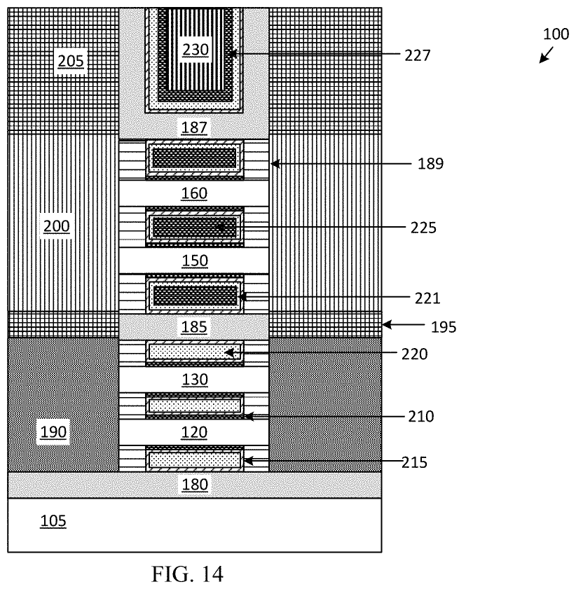

FIG. 14 illustrates the nano device 100 after the formation a metal cap 230, in accordance with the embodiment of the present invention. A metal cap 230 is formed on top of the second metal liner 227 to fill the space remaining within gap 209. The metal cap 230 can be comprised of, for example, Tungsten (W).

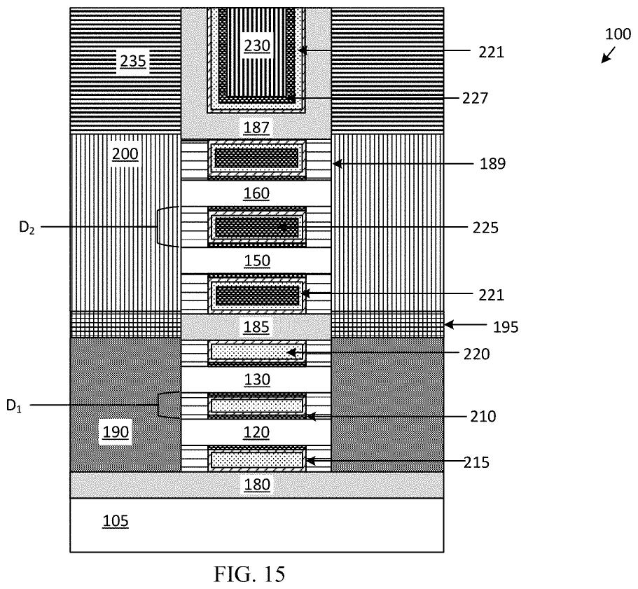

FIG. 15 illustrates the nano device 100 after the formation a metal connector 235, in accordance with the embodiment of the present invention. The ILD layer 205 is removed and a metal connector 235 is formed on top of the second source/drain 200 around the top spacer 187. Since the initial formation of the second group of sacrificial layers and the third group of sacrificial layers had different thickness (T₂>T₁) causes the space between the nano sheets/channels to be different. The channels/nano sheets (e.g., the third layer 120 and the fifth layer 130) in the lower device are spaced apart from each other at distance D1. The channels/nano sheets (e.g., the ninth layer 150 and the eleventh layer 160) in the upper device are spaced apart from each other at distance D2. Where distance D2 is greater than distance D1. The difference in thickness of the metal fills (e.g., the first metal layer 220 and the and the metal liner 221/ the second metal layer 225) allows for the upper and lower device to have different critical voltages (W_{FM}).

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A semiconductor device comprising:
a lower nano device that includes a plurality of stacked first nano sheets, wherein the first nano sheets are spaced apart from each other a first distance;
an upper nano device that includes a plurality of stacked second nano sheets, wherein the second nano sheets are spaced apart from each other a second distance, wherein the second distance is larger than the first distance.

2. The semiconductor device of claim 1, wherein the lower nano device further comprises:
a first metal layer located below and above each of the plurality of stacked first nano sheets, wherein the first metal layer has a first thickness T1.

3. The semiconductor device of claim 2, wherein the first metal layer is comprised of TiN.

4. The semiconductor device of claim 2, where the upper nano device further comprises:
a second metal layer located below and above each of the plurality of stacked second nano sheets;
a first metal liner located around the second metal layer, wherein the second metal layer and the first metal liner have a combined thickness T2.

5. The semiconductor device of claim 4, wherein the first metal liner is comprised of TiN, wherein the second metal layer is comprised of TiC or TiAlC.

6. The semiconductor device of claim 4, wherein the combined thickness T2 is greater than the first thickness T1.

7. The semiconductor device of claim 1, further comprising:
a top spacer located on top of the upper nano device, wherein the top spacer has a U-shape.

8. The semiconductor device of claim 7, further comprising:
a first metal liner is located on the inside surface of the top spacer.

9. The semiconductor device of claim 8, further comprising:
a second metal liner is located on the first metal liner located on the inside surface of the top spacer.

10. The semiconductor device of claim 9, further comprising:
a metal cap located on top of the second metal liner, wherein the metal cap is located within the U-shape top spacer.

11. The semiconductor device of claim 10, wherein the first metal liner is comprised of TiN, the second metal liner is comprised of TiC or TiAlC, and the metal cap is comprised of Tungsten (W).

12. A semiconductor device comprising:
a lower nano device that includes a plurality of stacked first nano sheets and a PFET material located around the plurality of stacked first nano sheets, wherein the first nano sheets are spaced apart from each other a first distance;
an upper nano device that includes a plurality of stacked second nano sheets a NFET material located around the plurality of stacked second nano sheets, wherein the second nano sheets are spaced apart from each other a second distance, wherein the second distance is larger than the first distance.

13. The semiconductor device of claim 12, wherein the lower nano device further comprises:
a first metal layer located below and above each of the plurality of stacked first nano sheets, wherein the first metal layer has a first thickness T1.

14. The semiconductor device of claim 13, wherein the first metal layer is comprised of TiN.

15. The semiconductor device of claim 13, where the upper nano device further comprises:
a second metal layer located below and above each of the plurality of stacked second nano sheets;
a first metal liner located around the second metal layer, wherein the second metal layer and the first metal liner have a combined thickness T2.

16. The semiconductor device of claim 15, wherein the first metal liner is comprised of TiN, wherein the second metal layer is comprised of TiC or TiAlC.

17. The semiconductor device of claim 15, wherein the combined thickness T2 is greater than the first thickness T1.

18. A method manufacturing a semiconductor device, the method comprising:
forming a lower nano device that includes a plurality of stacked first nano sheets and a plurality of first sacrificial layers, wherein a first sacrificial layer is located above and/or below each of the first nano sheets, wherein the each of the plurality of first sacrificial layers has a first thickness T1;
forming an upper nano device that includes a plurality of stacked second nano sheets and a plurality of second sacrificial layers, wherein a second sacrificial layer is located above and/or below each of the second nano sheets, wherein the each of the plurality of second sacrificial layers has a second thickness T2, wherein the second thickness T2 is greater than the first thickness T1.

19. The method of claim 18, further comprising:
selectively removing the plurality of first sacrificial layers and the plurality of second sacrificial layers;
forming a first metal layer in a space created by removing the plurality of first sacrificial layers and the plurality of second sacrificial layers, wherein the first metal layer pinches off space created by the removal of the plurality of first sacrificial layers, wherein the first metal layer forms a first metal liner in the space created by the removal of the plurality of second sacrificial layers.

20. The method of claim 19, further comprising:
forming a second metal layer on top of the first metal liner to pinch off the space created by the removal of the plurality of second sacrificial layers.
